(19) United States
(12) Patent Application Publication
(10) Pub. No.: US 2023/0048279 A1
(43) Pub. Date: Feb. 16, 2023

(54) OPTICAL DEVICE

(71) Applicant: Advanced Semiconductor Engineering, Inc., Kaohsiung (TW)

(72) Inventor: Yu-Wei CHEN, Kaohsiung (TW)

(73) Assignee: Advanced Semiconductor Engineering, Inc., Kaohsiung (TW)

(21) Appl. No.: 17/401,019

(22) Filed: Aug. 12, 2021

(51) Int. Cl. G01S 7/4863; H01L 25/065; G01S 7/484

(52) U.S. Cl. CPC G01S 7/4863; H01L 25/0655; G01S 7/484

(57) ABSTRACT

An optical element is provided. The optical device includes a carrier, a first receiver, and a second receiver. The first receiver is disposed on the carrier and configured to receive a first light. The second receiver is disposed on the carrier and configured to receive a second light. The first light and the second light have different frequency bands.

### BACKGROUND

### 1. Field of the Disclosure

The present disclosure relates to an optical device.

### 2. Description of the Related Art

Sensing technology is widely used in various applications, such as automobiles, internet of things (IoT) systems, surveillance, and many others. Visible and non-visible light detection may be collaboratively used for monitoring an environment. Such modules are, however, conventionally disposed in discrete arrangements. Therefore, conventional deployment of visible and non-visible light detection modules can cause problems with synchronization and image disparity.

### SUMMARY

In some arrangements, an optical device includes a carrier, a first receiver, and a second receiver. The first receiver is disposed on the carrier and configured to receive a first light. The second receiver is disposed on the carrier and configured to receive a second light. The first light and the second light have different frequency bands.

In some arrangements, an optical device includes a carrier, a transmitter, a first receiver, and a second receiver. The transmitter is operatively coupled to the carrier and configured to radiate a first light toward an object. The first receiver is operatively coupled to the carrier and configured to receive a second light reflected by the object. The second receiver is operatively coupled to the carrier and configured to receive a third light. The second light and the third light have different frequency bands.

In some arrangements, a method of manufacturing an optical device includes attaching a transmitter to a carrier; attaching a first receiver to the carrier, wherein the first receiver is configured to receive a first light; and attaching a second receiver to the carrier, wherein the second receiver is configured to receive a second light, wherein the first light and the second light have different frequency bands.

In some arrangements, an optical device includes a transmitter, a first receiver, and a second receiver. The first receiver is configured to receive a first light and generate a first image in response to the first light. The second receiver is configured to receive a second light and to generate a second image in response to the second light. The first image and the second image have substantially the same field of view.

### BRIEF DESCRIPTION OF THE DRAWINGS

Aspects of some arrangements of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an optical device according to some arrangements of the present disclosure.

FIG. 2A illustrates a top view of a receiver according to some arrangements of the present disclosure.

FIG. 2B illustrates a cross-sectional view of a structure shown in a box B1 of FIG. 2A according to some arrangements of the present disclosure.

FIG. 3 illustrates an interactive diagram of an optical device and an object according to some arrangements of the present disclosure.

FIG. 4A illustrates an image generated by an optical device according to some arrangements of the present disclosure.

FIG. 4B illustrates an image generated by an optical device according to some arrangements of the present disclosure.

FIG. 4C illustrates an image generated by an optical device according to some arrangements of the present disclosure.

FIG. 5 illustrates a cross-sectional view of an optical device according to some arrangements of the present disclosure.

FIG. 6 illustrates an interactive diagram of an optical device and an object according to some arrangements of the present disclosure.

FIG. 7 illustrates a cross-sectional view of an optical device according to some arrangements of the present disclosure.

FIG. 8 illustrates a cross-sectional view of an optical device according to some arrangements of the present disclosure.

FIG. 9 illustrates a cross-sectional view of an optical device according to some arrangements of the present disclosure.

FIG. 10 illustrates an interactive diagram of an optical device and an object according to some arrangements of the present disclosure.

FIG. 11, FIG. 12, FIG. 13, FIG. 14, FIG. 15, and FIG. 16 each illustrate one or more stages of an example method for manufacturing an optical device according to some arrangements of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different embodiments, arrangements, or examples, for implementing different features of the provided object matter. Specific examples of components and arrangements are described below to explain certain features of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, various different embodiments, examples, or arrangements may use a same reference numeral or letter to refer to a same or similar element for the purpose of clarity. Similarly shaded elements correspond to the same type of elements, although some of these elements may not be indicated using a reference numeral for the sake of clarity.

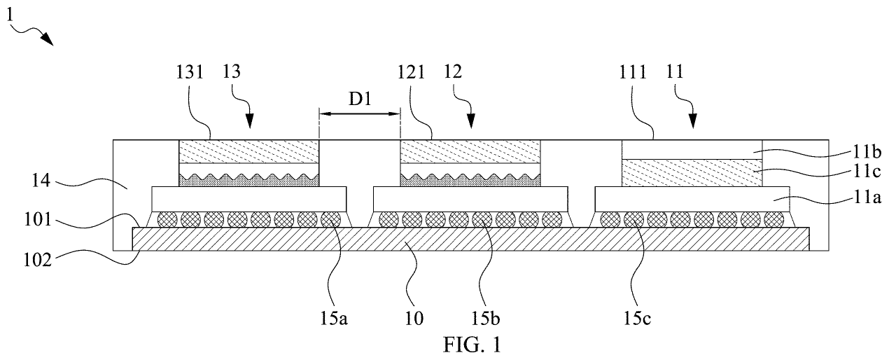

FIG. 1 illustrates a cross-sectional view of an optical device 1 according to some arrangements of the present disclosure. The optical device 1 may include a carrier 10, a transmitter 11, a receiver 12, a receiver 13, an encapsulant 14, and a plurality of connection elements 15a, 15b, and 15c.

The carrier 10 may have a surface 101 and a surface 102 opposite to the surface 101. The carrier 10 may have a plurality of conductive pads on the surface 101. The pluralities of connection elements 15a, 15b, and 15c may be disposed on the surface 101 of the carrier 10. The pluralities of connection elements 15a, 15b, and 15c may be coupled to (e.g., connected to, attached to, or bonded on) the plurality of conductive pads of the carrier 10. For example, each conductive pad on the surface 101 is coupled to a corresponding one of the connection elements 15a, 15b, and 15c. The carrier 10 may include one or more circuit layers (not shown) electrically connected to the plurality of conductive pads. The carrier 10 may electrically connect to electrical components attached to or bonded on the carrier 10.

In some arrangements, the carrier 10 may include a substrate. The carrier 10 may include, for example, a printed circuit board (PCB), such as a paper-based copper foil laminate, a composite copper foil laminate, or a polymer-impregnated glass-fiber-based copper foil laminate. Each of the connection elements 15a, 15b, and 15c may include, for example, a solder ball or a controlled collapse chip connection (C4) bump.

The transmitter 11 may be disposed on the surface 101 of the carrier 10. The surface 101 faces the transmitter 11. The transmitter 11 may have an active surface 111 facing away from the surface 101 of the carrier 10. The active surface 111 of the transmitter 11 may be exposed by (or from) the encapsulant 14. The transmitter 11 may be configured to transmit a signal through the active surface 111. The transmitter 11 may electrically connect to the carrier 10 through the connection elements 15c. The transmitter 11 may have an emitting region 11a, an optical element 11b, and a component 11c disposed between the emitting region 11a and the optical element 11b. The component 11c may include a transparent material. The component 11c may include a lens. The emitting region 11a is a region of the transmitter 11 that emits light by converting energy received via the element 15c into light (e.g., infrared light). The emitting region 11a may include a stack of semiconductor layers for emitting a light (e.g., a laser). Each semiconductor layer may include, for example but are not limited to, an III-V semiconductor layer. The optical element 11b may be disposed on the emitting region 11a. In some examples as shown, the emitting region 11a is between the optical element 11b and the carrier 10. The optical element 11b may be exposed by (or from) the encapsulant 14. The optical element 11b may be configured to diffract the light emitted from the emitting region 11a. Accordingly, the transmitter 11 may be configured to emit a diffracted light from the active surface 111. The transmitter 11 (e.g., the emitting region 11a) may be configured to emit (or radiate) an infrared light, in some examples. The transmitter 11 may be or include, for example but is not limited to, a gas laser, a dye laser, a metal-vapor laser, a solid-state laser, a semiconductor laser, a vertical-cavity surface-emitting laser (VCSEL), or so on.

The receiver 12 may be disposed on the surface 101 of the carrier 10. The surface 101 faces the receiver 12. The receiver 12 may have an active surface 121 facing away from the surface 101 of the carrier 10. The active surface 121 of the receiver 12 may be exposed by (or from) the encapsulant 14. The receiver 12 may electrically connect to the carrier 10 through the connection elements 15b. The receiver 12 may be configured to receive light at the active surface 121. The receiver 12 may be configured to receive an infrared light, in some examples. The receiver 12 may be configured to receive a light reflected by an object. The receiver 12 may include, for example but is not limited to, an infrared light image sensor.

The receiver 13 may be disposed on the surface 101 of the carrier 10. The surface 101 faces the receiver 13. The receiver 13 may have an active surface 131 facing away from the surface 101 of the carrier 10. The active surface 131 of the receiver 13 may be exposed by (or from) the encapsulant 14. The receiver 13 may electrically connect to the carrier 10 through the connection elements 15a. The receiver 13 may be configured to receive light at the active surface 131. The receiver 13 may be configured to receive a visible light, in some examples. The receiver 13 may be configured to receive a light reflected by the object. The receiver 13 may include, for example but is not limited to, a visible light image sensor.

The encapsulant 14 may disposed on and/or around the carrier 10. In some arrangements as shown, the encapsulant 14 may surround each of the transmitter 11, the receiver 12, and the receiver 13. The encapsulant 14 may cover a portion of one or more of the transmitter 11, the receiver 12, and the receiver 13. The lateral surface of the transmitter 11 may be covered by the encapsulant 14. The light emitted by the transmitter 11 is not transmitted through the lateral surface and is instead transmitted from the emitting region 11a through the active surface 111. The lateral surface of the receiver 12 may be covered by the encapsulant 14. The receiver 12 receives no light through the lateral surface and instead receives light through the active surface 121. The lateral surface of the receiver 13 may be covered by the encapsulant 14. The receiver 13 receives no light through the lateral surface and instead receives light through the active surface 131. The encapsulant 14 may be configured to prevent the receiver 12 and/or the receiver 13 from receiving environmental noise through the lateral surface thereof.

In some examples, the encapsulant 14 may include an opaque material. The opaque material of the encapsulant 14 may attenuates light (e.g., environmental noise). The lateral surfaces of the receiver 12 and/or the receiver 13 may not receive light or may only receive a subtle amount of light, such that the receiver 12 and/or the receiver 13 would not be influenced by the environmental noise. The encapsulant 14 may include an epoxy resin with fillers, a molding compound (e.g., an epoxy molding compound or other molding compound), a polyimide, a phenolic compound or material, a material with a silicone dispersed therein, or a combination thereof.

The optical device 1 may include a processor (not shown). The processor may be disposed on the surface 101 of the carrier 10 (e.g., adjacent to the transmitted 11 and the receivers 12 and 13) in some examples. In some examples, the processor may be embedded in the carrier 10. The processor may be disposed on the surface 102 of the carrier 10 in some examples. The processor may electrically connect to one or more of the transmitter 11, the receiver 12, and the receiver 13 through the carrier 10. The processor may be configured to control the operation of one or more of the transmitter 11, the receiver 12, and the receiver 13 through circuit layers of the carrier 10.

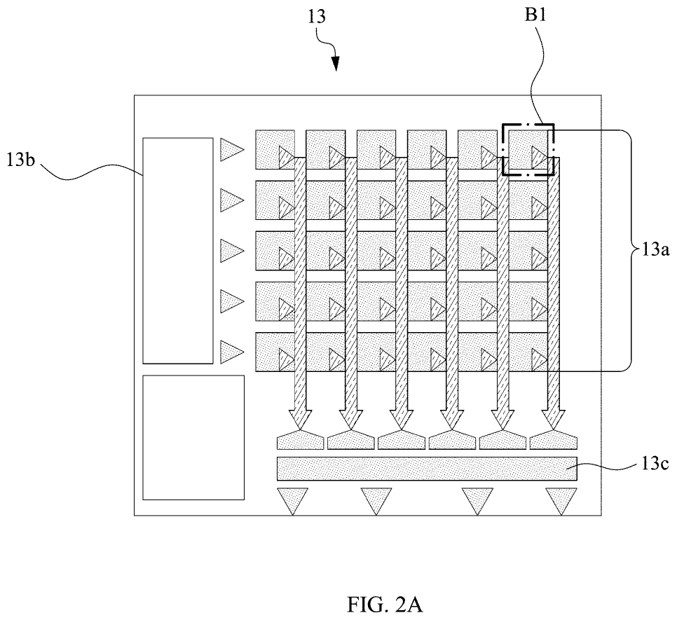

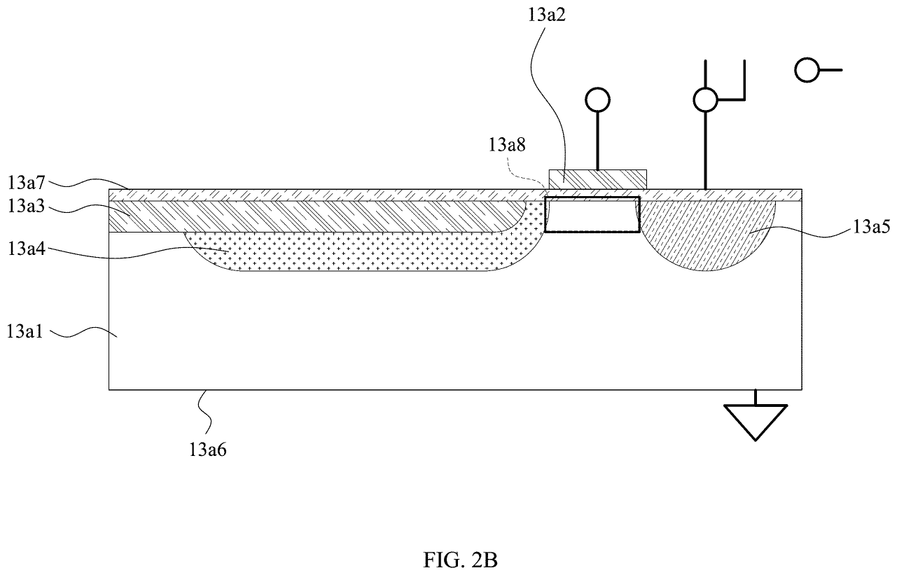

FIG. 2A illustrates a top view of the receiver 13 according to some arrangements of the present disclosure. The receiver 13 may include an array of pixels 13a, a control circuit 13b, and a processing circuit 13c. Each pixel of the array of pixels 13a may be configured to receive a green light, blue light, or red light. For example, one of the pixels 13a may be configured to receive a green light, while other ones of the pixels 13a adjacent to that one pixel may be configured to receive a green light, a blue light, or red light. In other words, two adjacent ones of the pixels 13a may receive a same color of light and/or different colors of light. Each pixel may be configured to receive a light and, generate an electrical signal (e.g., a current) in response to the light, and sends the electrical signal to the processing circuit 13b. The control circuit 13b of the receiver 13 may determine or receive a clock signal and operate based thereon. The control circuit 13b may be configured to control the array of pixels 13a and determine which portion(s) of the array of pixels 13a has transferred the electrical signals to the processing circuit 13c. The processing circuit 13c may be configured to process the electrical signals and generate one or more images based on the electrical signals.

FIG. 2B illustrates a cross-sectional view of a structure shown in a box B1 of FIG. 2A according to some arrangements of the present disclosure. In particular, FIG. 2B shows a pixel in the array of pixels 13a. As shown in FIG. 2B, a pixel may include a base layer 13a1, a transfer gate 13a2, a pinning region 13a3, a photodiode region 13a4, and a floating node 13a5. The transfer gate 13a2 may be operatively coupled to and controlled by the control circuit 13b. The light may be transmitted from an underside 13a6 of the base layer 13a1 (i.e., backside illumination, BSI) or from a top side 13a7 of the base layer 13a1 (i.e., frontside illumination, FSI). The underside 13a6 of the base layer 13a1 may face the surface 131 of the receiver 13. The pinning region 13a3 may determine the capacity of the photodiode region. The pinning region 13a3 may be configured to protect the photodiode region 13a4 from defects along the surface of the pixel. The photodiode region 13a4 may be configured to generate electrons in response to the light received from the underside 13a6 or the top side 13a7. When the transfer gate 13a2 is turned on by the control circuit 13b, the electrons may be transferred from the photodiode region 13a4 to the floating node 13a5 through a channel 13a8 below the transfer gate 13a2. In other words, the pixel may be configured to generate an electrical signal (e.g., a current) and the electrical signal may be transmitted from the floating node 13a5 to another device (not shown), for example, a selector device. The electrical signal may then be transferred to the processing circuit 13c.

The base layer 13a1 may be lightly doped. The transfer gate 13a2 may include polysilicon or metal. The pinning region 13a3 may be relatively heavily doped. The photodiode region 13a4 may be lightly doped with a type opposite to the pinning region 13a3 and the base layer 13a1. The floating node 13a5 may be heavily doped with a type the same as that of the photodiode region 13a4.

Furthermore, the receiver 12 may include a structure similar to those in FIG. 2A and FIG. 2B. Differences between the receiver 12 and the receiver 13 may include dopant (or dopant concentration), size, and thickness. For example, the dopant concentration of the receiver 12 may lighter than that of the receiver 13. For example, the size of the receiver 12 may be greater than that of the receiver 13. For example, the thickness of the receiver 12 may be greater than that of the receiver 13.

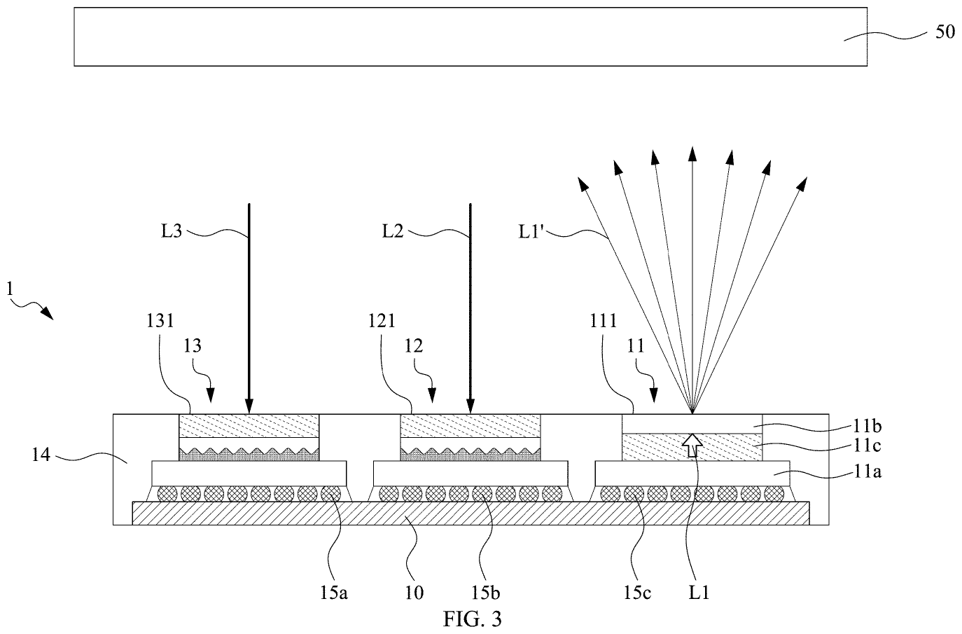

FIG. 3 illustrates an interactive diagram of the optical device 1 and an object 50 according to some arrangements of the present disclosure. The optical device 1 may be spaced apart from the object 50. While the object 50 is shown to have a rectangular shape, it should be understood that the object 50 can be one or more objects and can have any shape. The emitting region 11a of the transmitter 11 may be configured to emit light L1. The component 11c may be configured to transmit the L1. The optical element 11b of the transmitter 11 may be configured to diffract the light L1 into light L1′. The light L1′ may arrive at the object 50. The light L1′ may be reflected by the object 50 to be light L2. The receiver 12 may be configured to receive the light L2. The receiver 12 may be sensitive to light of a particular frequency band, e.g., a frequency band of infrared light, or to non-visible light. Accordingly, the receiver 12 may be a non-visible light image sensor. The frequency band of the light L1′ (or the light L1) may be substantially the same as the frequency band of the light L2. The transmitter 11 and the receiver 12 may be configured to collaboratively function as a light detecting and ranging (LIDAR). In some arrangements, the light L2 may include light reflected from objects in the environment other than the object 50. In some arrangements, the light L2 may include ambient light. The receiver 12 may be configured to receive ambient light (e.g., the light L2). The receiver 13 may be configured to receive light L3. The receiver 13 may be sensitive to light of a particular frequency band, e.g., a frequency band of visible lights. Accordingly, the receiver 13 may be a visible light image sensor. The light L2 and the light L3 may have different frequency bands.

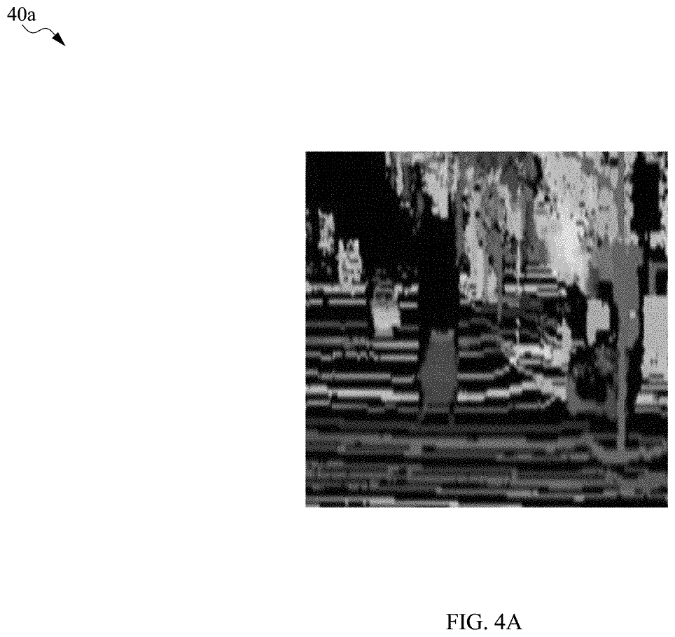

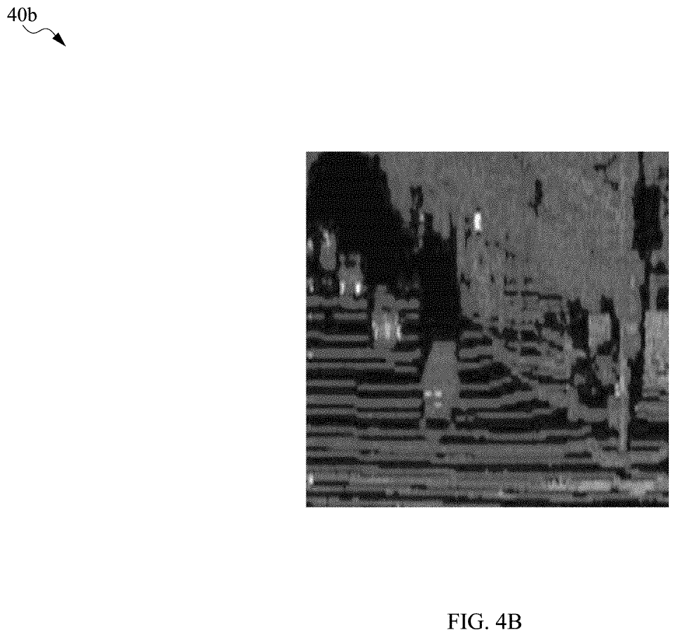

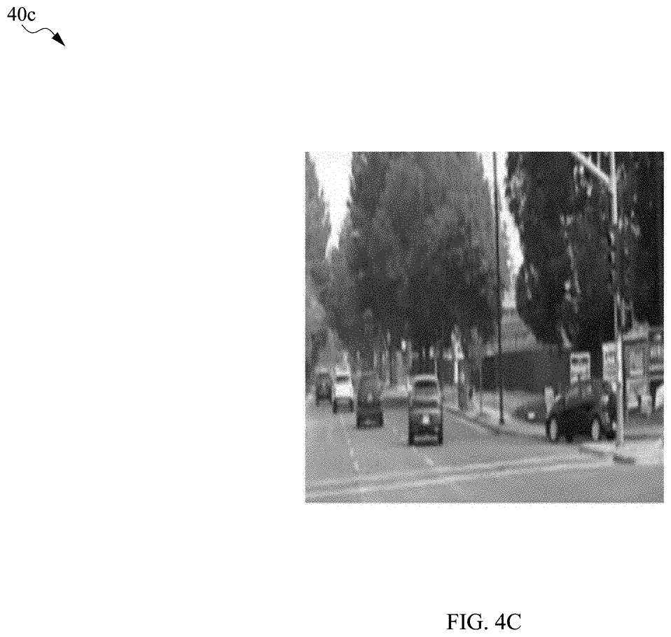

FIG. 4A illustrates an image 40a generated by the optical device 1 according to some arrangements of the present disclosure. The receiver 12 of the optical device 1 may be configured to receive the L2 and generate the image 40a in response to the light L2 as illustrated in FIG. 3. In some arrangements, the receiver 12 of the optical device 1 may be configured to generate the image 40a by calculating the time difference between the emitting time point of the light L1 and the receiving time point of the light L2. The image 40a may include or indicate information about the distance between the optical device 1 and the object 50.

FIG. 4B illustrates an image 40b generated by the optical device 1 according to some arrangements of the present disclosure. The receiver 12 of the optical device 1 may be configured to receive the L2 and generate the image 40b in response to the light L2 as illustrated in FIG. 3. In some arrangements, the receiver 12 of the optical device 1 may be configured to generate the image 40b by calculating the time difference between the emitting time point of the light L1 and the receiving time point of the light L2. The image 40b may include or indicate information about the reflectivity information of the object 50. The images 40a and 40b may be generated at the same time, or alternative times. The images 40a and 40b may be generated based on the same input (e.g., the light L2).

FIG. 4C illustrates an image 40c generated by the optical device 1 according to some arrangements of the present disclosure. The receiver 13 of the optical device 1 may be configured to receive the L3 and generate the image 40c in response to the light L3 as illustrated in FIG. 3. The image 40c may include color information of the object 50.

As shown in FIGS. 1 and 3, the receiver 12 and the receiver 13 are disposed side-by-side on the carrier 10. For example, a line parallel to the surface of the carrier 10 that is facing the receivers 12 and 13 traverses through the receivers 12 and 13. As shown, the receivers 12 and 13 may be spaced apart from each other with a portion of the encapsulant 14 therebetween. The receiver 12 and the transmitter 11 may be spaced apart from each other with a portion of the encapsulant 14 therebetween. The receiver 12 may be between the transmitter 11 and the receiver 13. Furthermore, a distance D1 between the receiver 12 and the receiver 13 in FIG. 1 may be less than a first predetermined value. For example, the first predetermined value may be 70 μm or less. As such, a difference between a field of view (FOV) of the image 40a and a FOV of the image 40c may be less than a second predetermined value. For example, the second predetermined value may be 5% or less. In some arrangements, the image 40a as generated by the receiver 12 and the image 40c as generated by the receiver 13 may have the substantially same FOV as shown in FIG. 4A and FIG. 4C. Similarly, the image 40b as generated by the receiver 12 and the image 40c as generated by the receiver 13 may have substantially the same FOV as shown in FIG. 4A and FIG. 4C due to the fact that the receivers 12 and 13 are disposed on the same carrier side-by-side and that the distance between the receivers 12 and 13 is less than the first predetermined value, which is negligible as compared to the distance between the optical device 1 and the object 50. Hence, the image disparity between the receiver 12 and the receiver 13 can be significantly improved.

The receiver 12 may be configured to receive a first clock signal from, e.g., a processor disposed on the carrier 10. The receiver 13 may be configured to receive a second clock signal from, e.g., a processor disposed on the carrier 10. In some examples, the first and second clock signals may be both received from the same processor disposed on the carrier 10. The first clock signal may be substantially synchronized with the first clock signal. As such, the receiver 12 and the receiver 13 may be configured to synchronously generate images based on the same scene. For example, the scene of the image 40a as generated by the receiver 12 may correspond to the scene of the image 40c as generated by the receiver 13. As such, the optical device 1 may directly use the image 40a, the image 40b, the image 40c without additional processing (e.g., filtering or interpolation) to calibrate the generated image.

Conventionally, an optical device may include a LiDAR and a visible light image sensor that are discretely arranged and connected to a processing unit. Discrete arrangement refers to the arrangement where the LiDAR and the visible light image sensor are disposed at different substrates or carriers and electrically connected to a common substrate (e.g., a motherboard). Such an optical device may have problems of image disparity resulting from the relatively long distance between the LiDAR and the visible light image sensor. Furthermore, synchronizing the clock signal of the LiDAR and the visible light image sensor is also difficult when they are discrete modules. The image generated by the LiDAR and the visible light may not be compatible because they correspond to different objects or scenes. The optical device should further calibrate the images generated by the LiDAR and the visible light image sensor to interpolate missing information and remove unwanted noise.

On the other hand, in accordance with the arrangements as shown in FIGS. 1-3, the LiDAR (e.g., the transmitter 11 and the receiver 12) and the visible light image sensor (e.g., the receiver 13) are integrated into a package. For example, the LiDAR (e.g., the transmitter 11 and the receiver 12) and the visible light image sensor (e.g., the receiver 13) are integrated as a same system in package (SiP). For example, the LiDAR (e.g., the transmitter 11 and the receiver 12) and the visible light image sensor (e.g., the receiver 13) are directly disposed on and electrically connected to a common substrate (e.g., the carrier 10). The distance between the LiDAR and the visible light image sensor can be reduced, which would improve the electrical performance of the optical device 1. For example, the optical device 1 can be configured to provide synchronized images generated by the receiver 12 and the receiver 13 with substantially the same FOV. The synchronization can be improved and the image disparity problem alleviated.

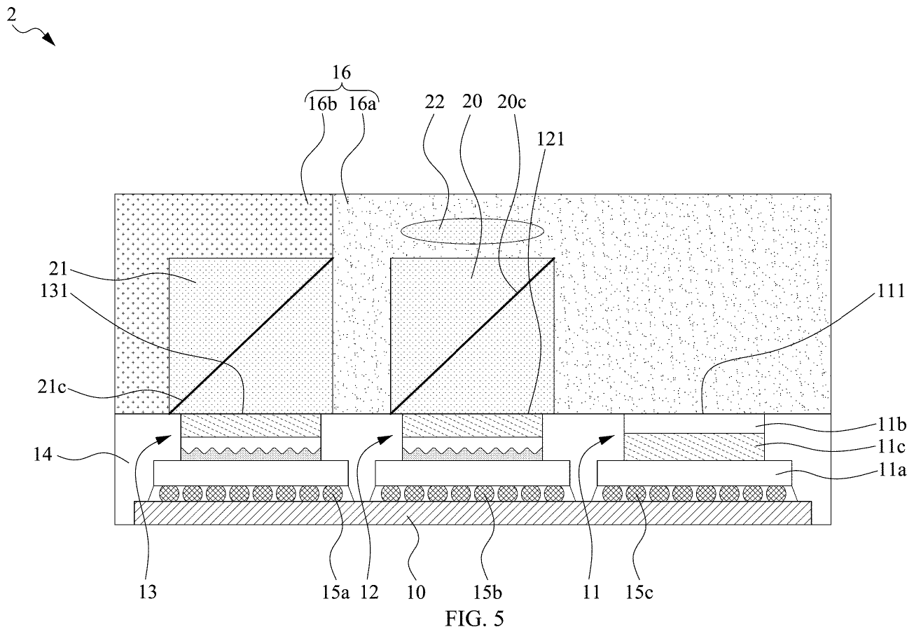

FIG. 5 illustrates a cross-sectional view of an optical device 2 according to some arrangements of the present disclosure. The optical device 2 of FIG. 5 is similar to the optical device 1 of FIG. 1, with differences therebetween as follows.

The optical device 2 may further include an encapsulant 16, an optical element 20, an optical element 21, and a lens 22.

The encapsulant 16 may be disposed on the carrier 10 in some examples. The transmitter 11 and the receivers 12 and 13 may be between at least a portion of the encapsulant 16 and the carrier 10. The encapsulant 16 may be disposed on the encapsulant 14 in some examples. The transmitter 11 and the receivers 12 and 13 may be between at least a portion of the encapsulant 16 and at least a portion of the encapsulant 14. The encapsulant 16 may include a transparent portion 16a and an opaque portion 16b connected to the transparent portion 16a. The transparent portion 16a may cover the optical element 20. The opaque portion 16b may cover or surround at least a portion of the optical element 21. The encapsulant 16 may include an epoxy resin with fillers, a molding compound (e.g., an epoxy molding compound or other molding compound), a polyimide, a phenolic compound or material, a material with a silicone dispersed therein, or a combination thereof. Alternatively, the encapsulant 16 may include an epoxy resin without fillers.

The optical element 20 may be over the receiver 12. The optical element 20 may be disposed on the receiver 12. As shown, the receiver 12 is between the optical element 20 and the carrier 10. The optical element 20 may be substantially aligned with the receiver 12. For example, an imaginary line perpendicular to a surface of the carrier 10 traverses portion of both the optical element 20 and the receiver 12. The optical element 20 may include a layer 20c that allows light of a particular frequency band, e.g., a frequency band of non-visible light to be transmitted therethrough. The layer 20c may reflect light of a particular frequency band, e.g., a frequency band of visible light. The optical element 20 may include a beam splitter.

The optical element 21 may be over the receiver 13. The optical element 21 may be disposed on the receiver 13. As shown, the receiver 13 is between the optical element 21 and the carrier 10. The optical element 21 may be substantially aligned with the receiver 13. For example, an imaginary line perpendicular to a surface of the carrier 10 traverses portion of both the optical element 21 and the receiver 13. The optical element 21 may include a layer 21c that allows light of a particular frequency band, e.g., a frequency band of non-visible light to be transmitted therethrough. The layer 21c may reflect light of a particular frequency band, e.g., a frequency band of visible light. The optical element 20 may include a beam splitter.

The lens 22 may be disposed on the optical element 20. As shown, the optical element 20 may be between the lens 22 and the receiver 12. The lens 22 may include a convex lens, in some arrangements. The lens 22 may be configured to transmit light from an object (e.g., the object 50). The lens 22 may be configured to focus light from an object. The lens 22 may enlarge the FOV of the image generated by the receiver 12 or the receiver 13.

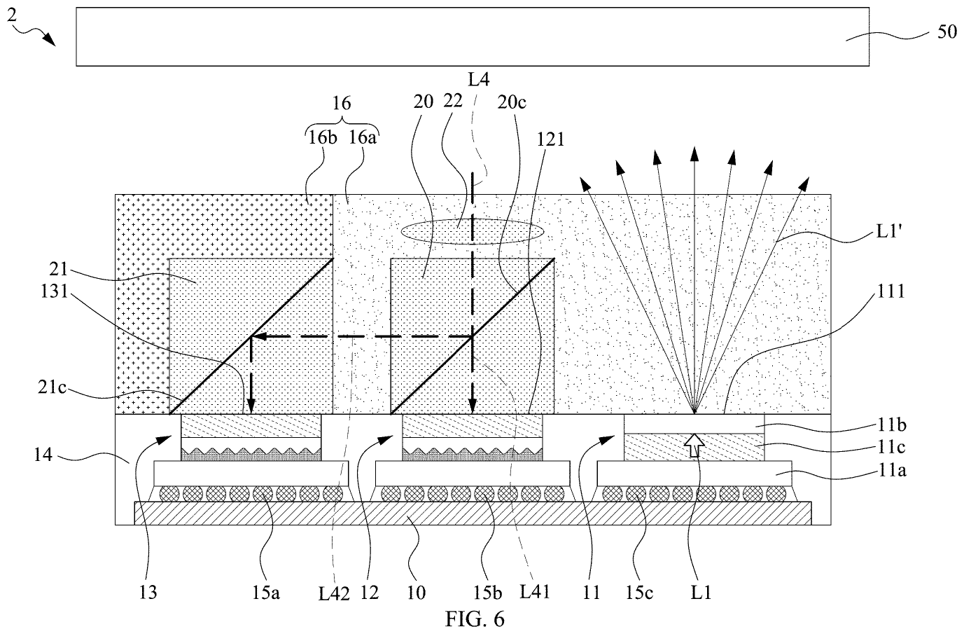

FIG. 6 illustrates an interactive diagram of the optical device 2 and an object 50 according to some arrangements of the present disclosure. The light L1′ emitted by the transmitter 11 may be transmitted through the transparent portion 16a of the encapsulant 16 and in direction of the object 50. The light L1′ may be reflected by the object 50 into a portion of light L4. In some arrangements, the light L4 may include light reflected from objects in the environment other than the object 50. In some arrangements, the light L4 may include ambient light. The light L4 may be transmitted through the transparent portion 16a of the encapsulant 16 and may be focused by the lens 22. The optical element 20 may be configured to receive the light L4 after being focused by the lens 22. The optical element 20 may be configured to split the light L4 into light L41 (or a portion L41 of the light L4) and light L42 (or a portion L42 of the light L4) by, for example, the layer 20c. The light L41 and the light L42 may have different frequency bands. The light L41 may have a frequency of non-visible light. The light L42 may have a frequency of visible light. In some arrangements, the light L41 may include an ambient light. In some arrangements, the light L42 may include an ambient light. The light L41 may include an infrared light and frequency bands corresponding thereto. The light L42 may include a visible light and frequency bands corresponding thereto. The optical element 20 may be configured to allow the light L41 to pass through and reflect the light L42. The optical element 20 may be configured to direct the light L41 toward the receiver 12 and direct the light L42 toward the optical element 21. The optical element 21 may be configured to reflect the light L42 to the receiver 13.

As shown in FIG. 6, the light L4 from the object 50 is split by the optical element 20 into the light L41 and the light L42. The light L41 is directed toward the receiver 12 and the light L42 is directed toward the receiver 13. The receiver 12 may be configured to receive ambient light and infrared light (collectively, the light L41). The receiver 12 may be configured to receive ambient light and the visible light (collectively, the light L42). As such, an image generated by the receiver 12 in response to the light L41 and an image generated by the receiver 13 may have the same FOV. The problems of image disparity can thus be addressed.

Furthermore, the distance between the receiver 12 and the receiver 13 of the optical device 2 may be less than the first predetermined value as discussed. Hence, the difference between the FOV of the images generated by the receiver 12 and the receiver 13 can be reduced by the shorter distance therebetween and a well-designed optical structure (e.g., the optical element 20, and the optical element 21, and the lens 22).

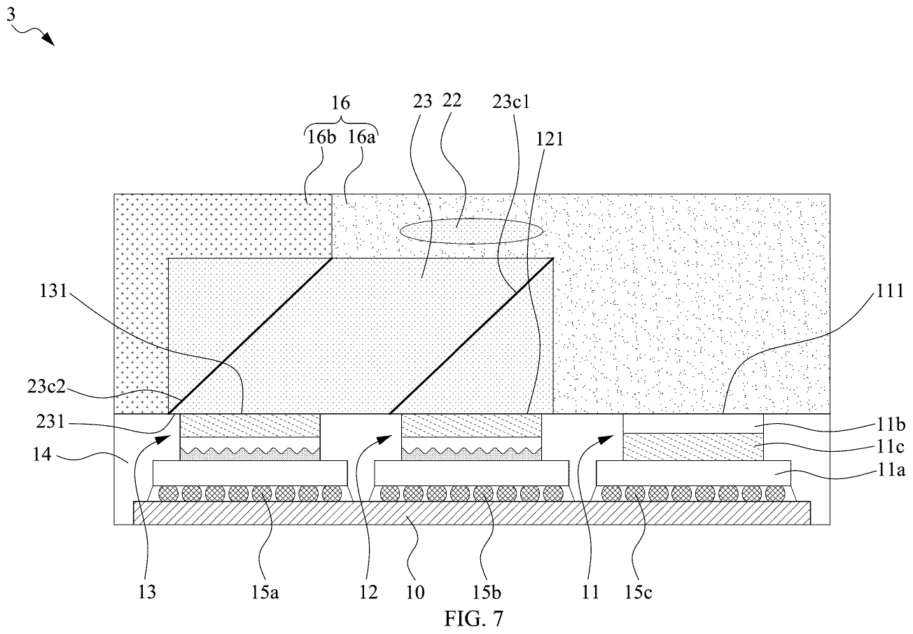

FIG. 7 illustrates a cross-sectional view of an optical device 3 according to some arrangements of the present disclosure. The optical device 3 of FIG. 7 is similar to the optical device 2 of FIG. 5, with differences therebetween as follows.

The optical device 3 may include an optical element 23 rather than the optical elements 20 and 21 of the optical device 2. In other words, the optical elements 20 and 21 may be formed in one piece (e.g., manufactured as a unitary element). The optical element 23 may be supported by the receiver 12 (e.g., the active surface 121) and the receiver 13 (e.g., the active surface 131). The receivers 12 and 13 may be between the optical element 23 and the carrier 10. The optical element 23 has a bottom surface 231 substantially aligned with (e.g., coplanar with) the active surface 121 of the receiver 12 and the active surface 131 of the receiver 13. In some examples, the bottom surface 231 may contact one or both of the active surfaces 121 and 131. The optical element 23 may include a layer 23c1 and a layer 23c2. The layer 23c1 may be similar to the layer 20c of the optical element 20. The layer 23c2 may be similar to the layer 21c of the optical element 21. The optical element 23 may be disposed on the receiver 12 and the receiver 13.

When forming the optical element 23 of the optical device 3, alignment errors can occur, such as between the optical element 23 and the receiver 12 or between the optical element 23 and the receiver 13. When forming the optical element 20 and the optical element 21 of the optical device 2, additional alignment errors between the optical element 20 and the optical element 21 should be considered. Hence, the optical device 3 may have relatively few alignment errors.

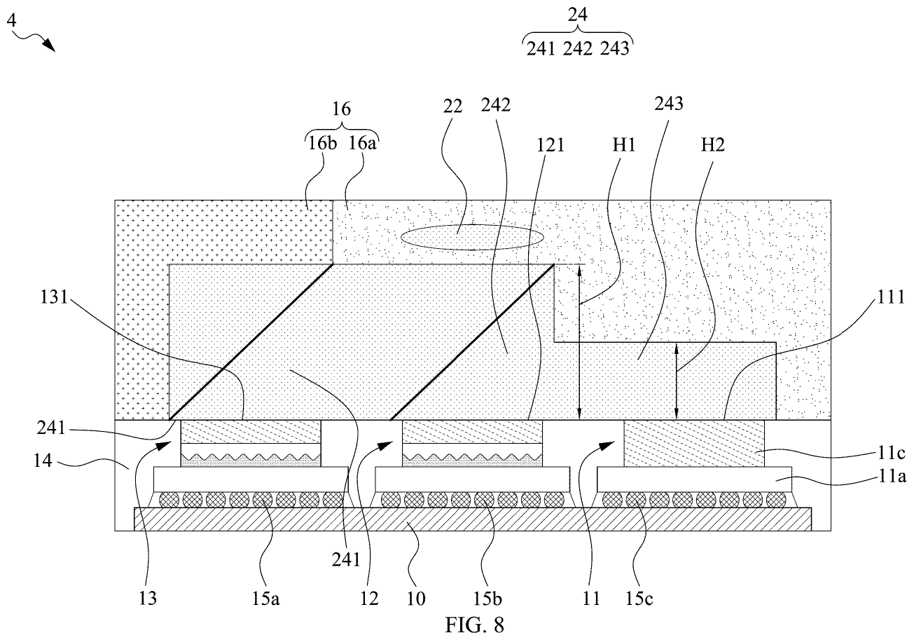

FIG. 8 illustrates a cross-sectional view of an optical device according to some arrangements of the present disclosure. The optical device 4 of FIG. 8 is similar to the optical device 2 of FIG. 5, with differences therebetween as follows.

The optical device 3 may include an optical element 24 rather than the optical elements 20 and 21 of the optical device 2. The optical element 24 may include a portion 241 (or an optical element 241), a portion 242 (or an optical element 242), and a portion 243 (or an optical element 243) formed in one piece (e.g., manufactured as a unitary element). The portions 241 and 242 of the optical element 24 may be similar to the optical element 23. The portions 241 and 242 may be connected to each other. The portion 241 may be disposed on or over the receiver 13. The portion 241 may have a bottom surface substantially aligned with (e.g., coplanar with) the active surface 131 of the receiver 13. In some examples, the bottom surface of the portion 241 may contact the active surface 131. The portion 242 may be disposed on or over the receiver 12. The portion 242 may have a bottom surface substantially aligned with (e.g., coplanar with) the active surface 121 of the receiver 12. In some examples, the bottom surface of the portion 242 may contact the active surface 121. The portion 243 of the optical element 24 may be disposed on the transmitter 12. The portion 243 may have a bottom surface substantially aligned with (e.g., coplanar with) the active surface 111 of the transmitter 11. In some examples, the bottom surface of the portion 243 may contact the active surface 111. The transmitter 11 and receivers 12 and 13 may be between the optical element 24 and the carrier 10. The portion 243 of the optical element 24 may include a diffractive optical element (DOE), such as a beam shaper, a beam splitter, a diffuser, a diffractive focusing lenses, and/or a grating. The portion 243 of the optical element 24 may be configured to modify light from the transmitter 11. In some arrangements, the portion 243 of the optical element 24 may be configured to shape, split, diffuse, or diffract light from the transmitter 11.

The portion 242 may have a height H1. The portion 243 may have a height H2. The height H1 may be greater than the height H2.

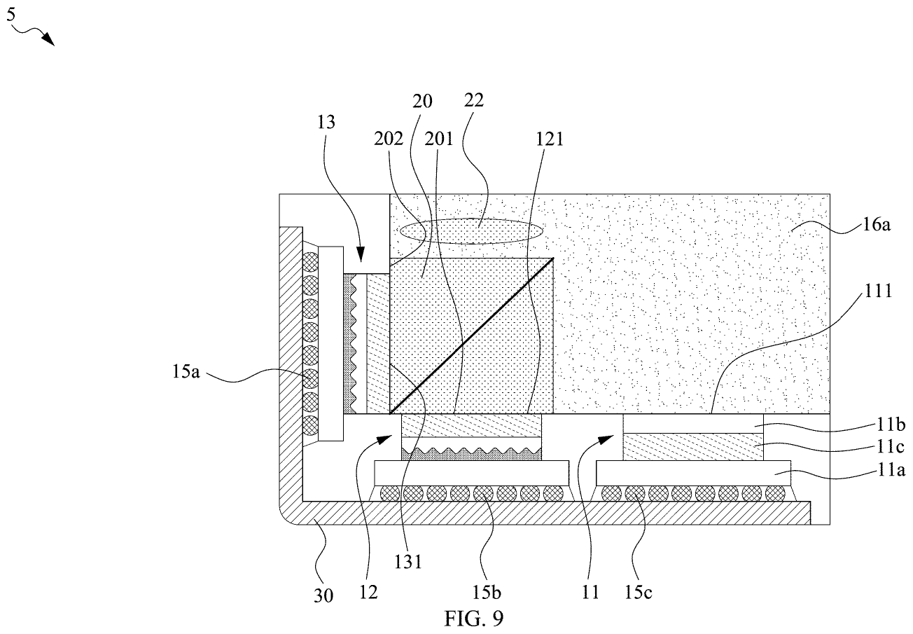

FIG. 9 illustrates a cross-sectional view of an optical device according to some arrangements of the present disclosure. The optical device 5 of FIG. 9 is similar to the optical device 2 of FIG. 5, with differences therebetween as follows.

The optical device 5 may have a carrier 30 including a flexible or adjustable material. The carrier 30 may be configured to support the transmitter 11. The carrier 30 may also be configured to support the receiver 12 and the receiver 13. The shape of the carrier 30 can be manipulated to include a first portion and a second portion that form a right angle, an acute angle, or an obtuse angle. In other words, the carrier 30 may be bent at a right angle, an acute angle, or an obtuse angle. The carrier 30 may be configured to adjust the relative positions of the receiver 12 and the receiver 13, in some examples. For example, the relative positions of the receiver 12 and the receiver 13 may be adjustable through the carrier 30. As shown, the carrier 30 can be bent at a portion of the carrier 30 between the receivers 12 and 13 to adjust the relative positions of the receivers 12 and 13. The active surface 121 of the receiver 12 may be substantially perpendicular to the active surface 131 of the receiver 13 in some arrangements. The optical element 20 may have a surface 201 in contact with the active surface 121 and a surface 202 connected to the surface 201 and in contact with the active surface 131.

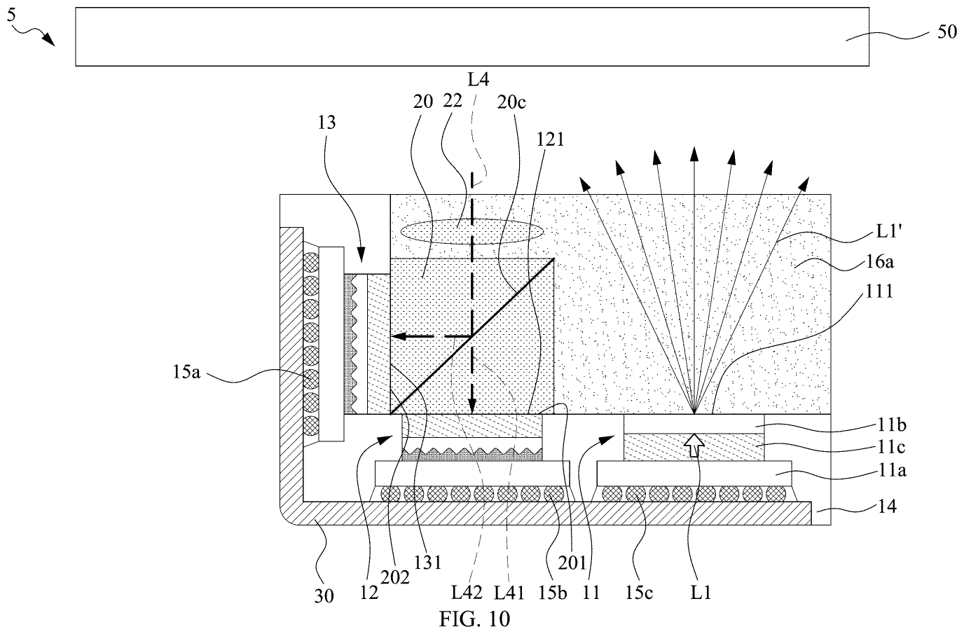

FIG. 10 illustrates an interactive diagram of the optical device 5 and an object 50 according to some arrangements of the present disclosure. The light L4 may be split by the optical element 20 into the light L41 (e.g., an infrared light) and the light L42 (e.g., a visible light). In some arrangements, the light L41 may include an ambient light. In some arrangements, the light L42 may include an ambient light. The optical element 20 may be configured to, alone, direct the light L41 toward the receiver 12 and the light L42 toward the receiver 13. The optical path of the optical device 5 may be relatively short. For example, the optical path of the optical device 5 may be shorter than that of the optical device 2 as illustrated in FIG. 6. As such, the design of the optical path of the optical device 5 may be relatively simple. The optical device 5 can have a relatively low amount of alignment error and be relatively small in size.

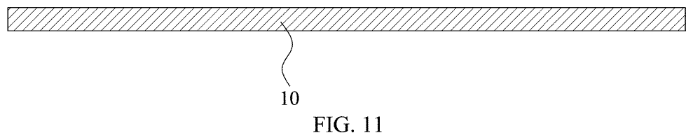

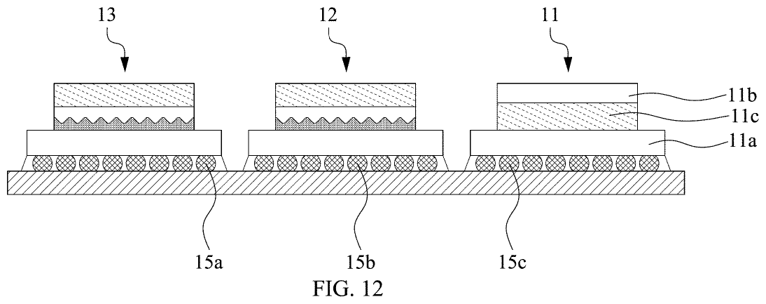

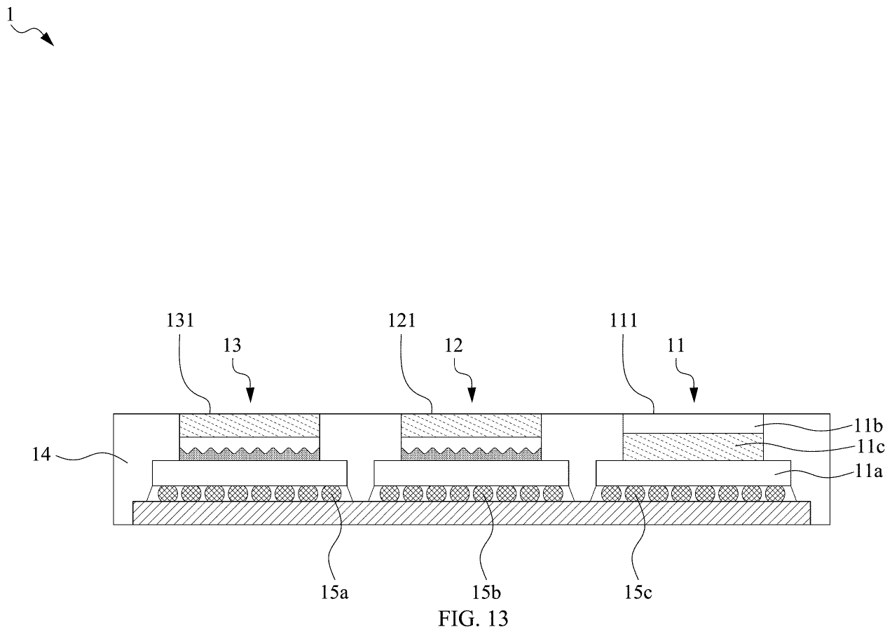

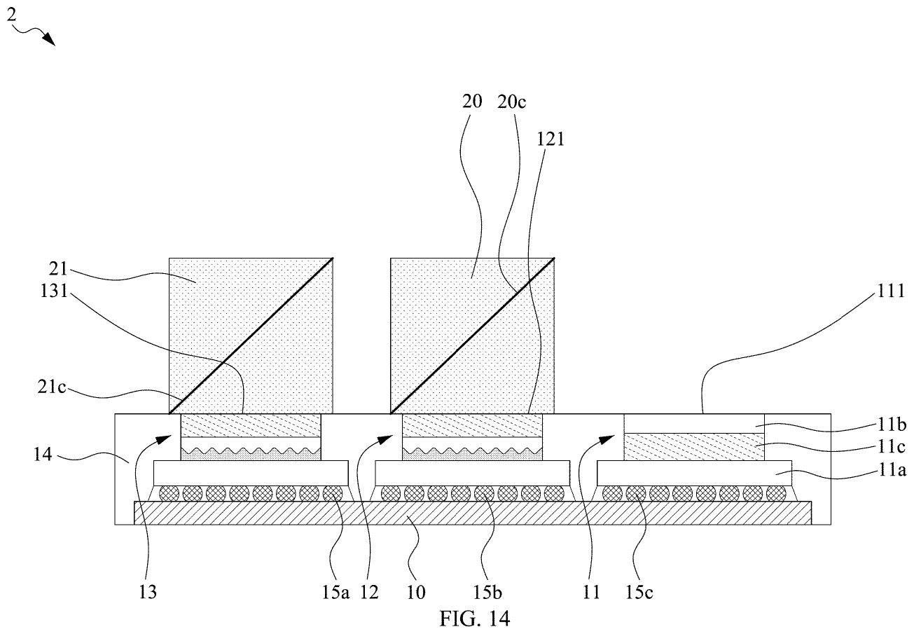

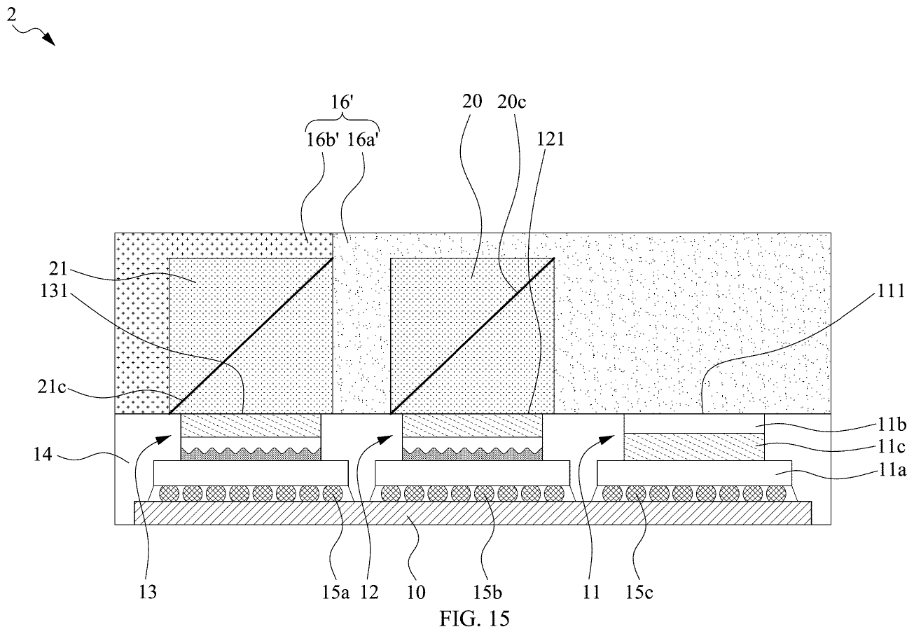

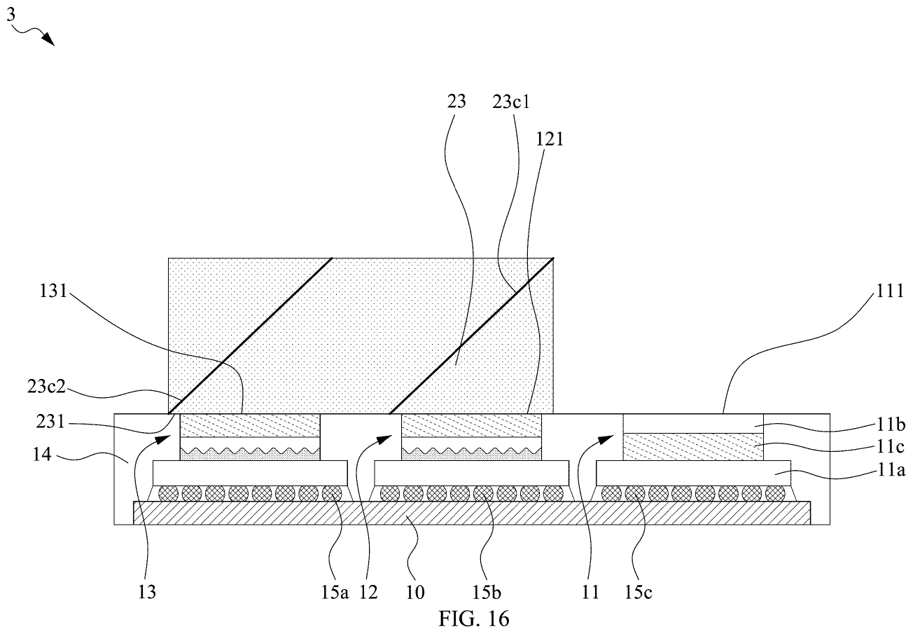

FIG. 11, FIG. 12, FIG. 13, FIG. 14, FIG. 15, and FIG. 16 each illustrate one or more stages of an example method for manufacturing an optical device according to some arrangements of the present disclosure.

Referring to FIG. 11, a carrier 10 may be provided (e.g., manufactured according to conventional methods). Referring to FIG. 12, a transmitter 11 may be attached to the carrier 10 through a plurality of connection elements 15c. A receiver 12 may be attached to the carrier 10 through a plurality of connection elements 15b. Furthermore, a receiver 13 may be attached to the carrier 10 through a plurality of connection elements 15a. The light received by the receiver 12 and the light received by the receiver 13 may be of different frequency bands.

Referring to FIG. 13, an encapsulant 14 may be formed to cover the transmitter 11, the receiver 12, and the receiver 13 to form the optical device 1 as illustrated in FIG. 1. The encapsulant 14 may include an opaque material. An active surface 111 of the transmitter 11 may be exposed by (or from) the encapsulant 14. An active surface 121 of the receiver 12 may be exposed by (or from) the encapsulant 14. An active surface 131 of the receiver 13 may be exposed by (or from) the encapsulant 14.

Referring to FIG. 14, an optical element 20 may be formed on the receiver 12 and an optical element 21 may be formed on the receiver 13. The optical element 20 may be configured to split a light into a first portion and a second portion by, for example, a layer 20c. The optical element 21 may be configured to split a light into a first portion and a second portion by, for example, a layer 21c.

Referring to FIG. 15, an encapsulant 16′ may be formed to cover the optical element 20 and the optical element 21. The encapsulant 16′ may include a transparent portion covering the optical element 20 and an opaque portion covering the optical element 21.

Subsequently, a lens (e.g., the lens 22) may be formed on the encapsulant 16′ and an additional encapsulating layer may be formed on the encapsulant 16′ to form the optical device 2 as illustrated in FIG. 5.

Referring to FIG. 16, an optical element 23 may be formed on the receiver 12 and the receiver 13. The optical element 23 may be configured to direct a first portion of light toward the receiver 12 and a second portion of light toward the receiver 13.

Subsequently, an encapsulant may be formed to cover the optical element 23 similar to FIG. 14. A lens may be then formed on the encapsulant and an additional encapsulating layer may be formed on the encapsulant to form the optical device 3 as illustrated in FIG. 7.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to±10% of that numerical value, such as less than or equal to±5%, less than or equal to±4%, less than or equal to±3%, less than or equal to±2%, less than or equal to±1%, less than or equal to±0.5%, less than or equal to±0.1%, or less than or equal to±0.05%. For example, two numerical values can be deemed to be “substantially” the same or equal if a difference between the values is less than or equal to±10% of an average of the values, such as less than or equal to±5%, less than or equal to±4%, less than or equal to±3%, less than or equal to±2%, less than or equal to±1%, less than or equal to±0.5%, less than or equal to±0.1%, or less than or equal to±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An optical device, comprising
a carrier;
a first receiver disposed on the carrier and configured to receive a first light; and
a second receiver disposed on the carrier and configured to receive a second light;
wherein the first light and the second light have different frequency bands.

2. The optical device of claim 1, further comprising an encapsulant covering a portion of the first receiver and a portion of the second receiver.

3. The optical device of claim 1, further comprising a transmitter disposed on the carrier, wherein the transmitter is configured to emit a third light toward an object, and a frequency band of the third light is substantially the same as the frequency band of the first light.

4. The optical device of claim 1, further comprising a transmitter disposed on the carrier, wherein the transmitter and the first receiver are configured to collaboratively perform light detection and ranging.

5. The optical device of claim 1, wherein the first receiver includes a non-visible light image sensor and the second receiver includes a visible light image sensor.

6. The optical device of claim 1, further comprising a first optical element over the first receiver, wherein the first optical element is configured to receive a fourth light and split the fourth light into the first light and the second light.

7. The optical device of claim 6, wherein the first optical element is configured to direct the first light toward the first receiver and to direct the second light toward a second optical element.

8. The optical device of claim 6, wherein the first optical element is supported by the first receiver and the second receiver.

9. The optical device of claim 1, wherein the first receiver is configured to generate a first image based on the first light and the second receiver is configured to generate a second image based on the second light, and wherein the first image and the second image include substantially the same field of view (FOV).

10. The optical device of claim 1, wherein the first receiver is configured to generate a first image based on the first light and the second receiver is configured to generate a second image based on the second light, and wherein the first image has a first FOV and the second image has a second FOV, and wherein, when a distance between the first receiver and the second receiver is less than a first predetermined value, a difference between the first FOV and the second FOV is less than a second predetermined value.

11. The optical device of claim 7, further comprising a second encapsulant disposed on the carrier, wherein the second encapsulant has a transparent portion covering the first optical element and an opaque portion covering the second optical element.

12. The optical device of claim 7, further comprising a transmitter disposed on the carrier and a third optical element disposed on the transmitter, wherein the third optical element is configured to modify the light emitted by the transmitter.

13. The optical device of claim 1, wherein the carrier is configured to support the first receiver and the second receiver, and configured to adjust the relative positions of the first receiver and the second receiver.

14. An optical device, comprising
a carrier;
a transmitter operatively coupled to the carrier and configured to radiate a first light toward an object;
a first receiver operatively coupled to the carrier and configured to receive a second light reflected by the object; and
a second receiver operatively coupled to the carrier and configured to receive a third light reflected by the object,
wherein the first light and the third light have different frequency bands.

15. The optical device of claim 14, wherein the first receiver is configured to generate a first image based on the second light and the second receiver is configured to generate a second image based on the third light, and wherein the first image and the second image include substantially the same field of view (FOV).

16. The optical device of claim 14, wherein the second light and the third light have different frequency bands.

17. The optical device of claim 14, wherein the first receiver is configured to receive a first clock signal, and the second receiver is configured to receive a second clock signal substantially synchronized with the first clock signal.

18. The optical device of claim 14, further comprising a first optical element configured to split a fourth light reflected by the object into the second light and the third light.

19. The optical device of claim 18, further comprising a second optical element configured to direct the third light to the second receiver.

20. The optical device of claim 14, further comprising a first encapsulant having an opaque material configured to prevent environmental noise from being received by the first receiver and/or the second receiver.

21. The optical device of claim 20, further comprising a second encapsulant disposed on the first encapsulant, wherein the second encapsulant has a first portion transparent to the second light and the third light, and a second portion opaque to environment noise.

22. The optical device of claim 14, wherein the first receiver has an active surface and the second receiver has an active surface substantially perpendicular to the active surface of the first receiver.
